(19) United States
(12) Patent Application Publication
(10) Pub. No.: US 2025/0112483 A1
(43) Pub. Date: Apr. 3, 2025

(54) TECHNIQUES TO ENABLE SMART BATTERY CHARGING

(71) Applicant: Intel Corporation, Santa Clara, CA (US)

(72) Inventors: Naoki Matsumura, San Jose, CA (US); Ajit Kadaveru, Fairfax, VA (US); Jagadish Singh, Bangalore (IN)

(21) Appl. No.: 18/478,727

(22) Filed: Sep. 29, 2023

(51) Int. Cl. H02J 7/00; G01R 31/392

(52) U.S. Cl. CPC H02J 7/0069; G01R 31/392; H02J 7/005; H02J 7/0071; H02J 7/007194

(57) ABSTRACT

Embodiments herein relate to techniques to facilitate a user to enable one or more smart battery charging algorithms on a device to control charging of a battery associated with the device. A control circuitry of the device may receive usage data associated with a battery of the device (e.g., via a battery interface). The control circuitry may predict a future health metric of the battery based on the usage data. The control circuitry may compare the future metric to a threshold and trigger, based on the comparison, display of information about one or more smart charging algorithms to the user. Additionally, or alternatively, the control circuitry may generate predicted performance information associated with multiple charging configurations and present the performance information to the user. Other embodiments may be described and claimed.

### BACKGROUND

Lithium ion (Li-ion) rechargeable batteries are widely used for mobile devices (e.g., laptops and smartphones) and Electric Vehicles (EVs). While the batteries provide long battery-life/driving-range at the beginning of their life cycle, they degrade when full charging is repeated and the batteries experience high state-of-charge for long time. The batteries also degrade faster when fast charging is repeated. Users typically desire to mitigate battery degradation so that battery-life/driving-range stays long through the product life.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 illustrates an example device in accordance with various embodiments.

FIG. 2 illustrates an example graphical depiction of a predicted state of health of a battery and a comparison to a corresponding threshold, in accordance with various embodiments.

FIG. 3 illustrates an example graphical depiction of a predicted state of health for two different smart charging algorithms, in accordance with various embodiments.

FIG. 4 illustrates an example of performance information that may be displayed to a user, in accordance with various embodiments.

FIG. 5 illustrates another example of performance information that may be displayed to a user, in accordance with various embodiments.

FIG. 6 illustrates an example process to perform various embodiments herein.

FIG. 7 illustrates another example process to perform various embodiments herein.

FIG. 8 illustrates an example of components that may be present in a computing system for implementing the techniques (e.g., operations, processes, methods, and methodologies) described herein, in accordance with various embodiments.

### DETAILED DESCRIPTION

Various embodiments herein provide techniques to facilitate a user to enable one or more smart battery charging algorithms on a device to control charging of a battery associated with the device. The techniques may be used for a battery-powered device, such as a computer system, smart phone, tablet, electric vehicle, etc.

In some embodiments, a control circuitry may receive usage data associated with a battery and/or system of the device. The control circuitry may be implemented in the device and/or in a remote system that is in communication with the device. The control circuitry may predict a future metric of the battery based on the usage data. For example, the predicted metric may be a battery state of health, a battery degradation rate, and/or another suitable metric. In embodiments, the control circuitry may compare the future metric to a threshold and trigger, based on the comparison, display of information about one or more smart charging algorithms to the user. For example, the display of information may be triggered if the predicted battery state of health is less than a corresponding threshold or if the predicted battery degradation rate is greater than a corresponding threshold. The display of information may provide the user with an option to switch to a different charging algorithm, such as a smart charging algorithm.

The displayed information may include, for example, a suggestion to use a different charging algorithm, the predicted metric(s), performance information associated with a charging configuration that is currently being used, and/or performance information associated with at least one other charging configuration to enable the user to compare the charging configurations.

In some embodiments, the device may have multiple smart charging configurations available to use. The smart charging configurations may correspond to different smart charging algorithms, pre-defined (e.g., non-smart) charging algorithms, and/or different parameters for a given smart or pre-defined charging algorithm. In embodiments, the control circuitry may generate performance information for the plurality of smart charging configurations. The performance information may be displayed to the user of the device to enable the user to compare the charging configurations and select one of the charging configurations to use.

The performance information may be displayed to the user based on a triggering condition and/or upon request by the user. For example, the triggering condition may be a predicted metric being above or below a corresponding threshold as described above, a determination that a different charging configuration is predicted to perform better (e.g., based on the usage data), expiration of a timer (e.g., to periodically display the performance information for the available charging configurations to the user), and/or another suitable triggering condition.

Many existing systems offer a smart charging algorithm which avoids full charging and/or fast charging and extends battery longevity. For example, the present inventors have previously developed a context-based battery charging scheme that avoids unnecessary full charging and fast charging by analyzing the past battery usage with machine-learning and/or deep-learning. The scheme may selectively employ full charging and/or fast charging based on the past battery usage (e.g., under similar circumstances to present circumstances).

Smart charging algorithms are typically disabled by default, and thus the end user needs to enable the algorithm. However, it is difficult for the end user to know what effect the smart charging algorithm has or if they should enable the algorithm.

Various embodiments herein may address these shortcomings of prior systems and encourage users to activate a smart charging algorithm that is predicted to improve performance of the device and/or meets the user's needs.

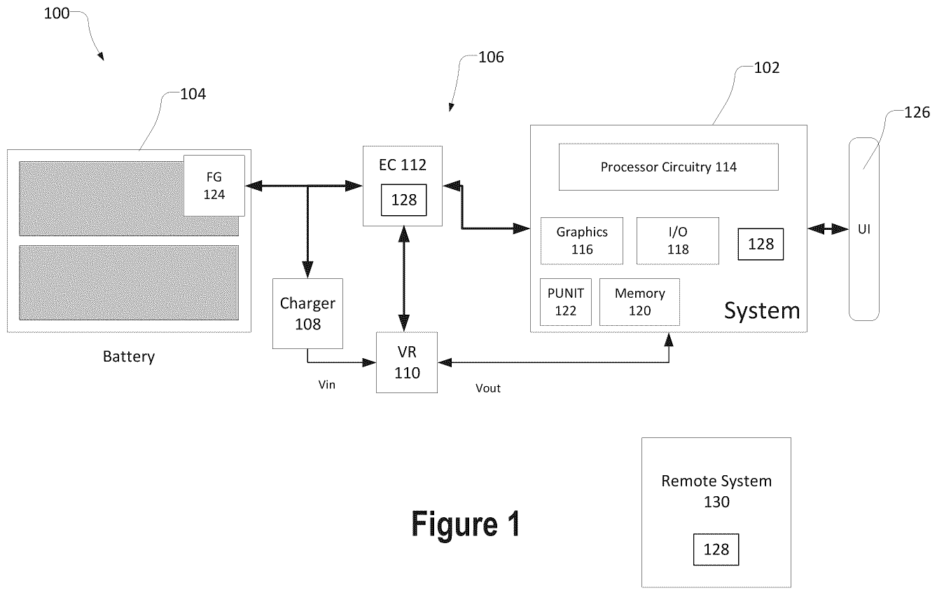

FIG. 1 illustrates example components of a device 100 in accordance with various embodiments. The device 100 may include system circuitry 102 that is powered by a battery 104. The device 100 may further include power management circuitry 106 coupled to the battery 104 and system circuitry 102. The power management circuitry 106 may include a charger 108 to charge the battery 104, and a voltage regulator (VR) 110 to receive an input voltage from the battery 104 and generate an output voltage that is provided to the system circuitry 102. Furthermore, the power management circuitry 106 may include an embedded controller (EC) 112 to control the charger 108.

In various embodiments, the system circuitry 102 may include any suitable components depending on the type of device 100. For example, as shown in FIG. 1, the system circuitry 102 may include one or more of processor circuitry 114 (e.g., central processing unit (CPU) circuitry), graphics processor circuitry 116, input/output (I/O) circuitry 118, memory 120, power control unit (punit) 122, and/or another suitable component. The components of system circuitry 102 may be disposed in one or more integrated circuit (IC) dies. In some embodiments, the system circuitry 102 may be integrated into a system-on-chip (SoC) or system-in-package (SiP) configuration.

Although the power management circuitry 106 is shown in FIG. 1 as separate from the processor circuitry 102 and battery 104, in some embodiments one or more components of the power management circuitry 106 may be included in the system circuitry 102, the battery 104, and/or another component of the device 100. For example, one or more components of the power management circuitry 106 may be included on a same IC die as one or more components of the system circuitry 102 and/or in one or more separate IC dies that are integrated in a same IC package as one or more components of the system circuitry 102.

In various embodiments, the device 100 may include a fuel gauge (FG) 124 coupled to and/or integrated into the battery 104. The fuel gauge 114 may indicate a state of charge of the battery 104.

The device 100 may further include a user interface (UI) 126 coupled to the system circuitry 102. The UI 126 may include a display (e.g., a touchscreen display or a non-touchscreen display) and one or more user input mechanisms (e.g., the touchscreen display, one or more buttons, a keyboard, a trackpad/mouse, etc.).

In various embodiments, the device 100 may include control circuitry 128 to implement aspects of embodiments herein. The control circuitry 128 may be at least partially included any suitable component of device 100, such as the power management circuitry 106 (e.g., in EC 112), the system circuitry 102 (e.g., in processor circuitry 114 and/or punit 122), and/or another suitable component of device 100. Alternatively, part or all of the control circuitry 128 may be in a remote system 130 in communication with the device 100 (e.g., via a communication network).

The control circuitry 128 may receive usage information associated with the battery 104 and/or system circuitry 102 over a period of time. In some embodiments, the period of time may be an entire history of the device 100 or a time period from a predefined point in the past up to the present (e.g., a number of most recent days/weeks/months). In some embodiments, the usage information for the time period may be extrapolated to a longer time period for the analysis. For example, usage data for a first time period (e.g., 8 weeks) may be used to simulate usage data for a second, longer time period (e.g., 24 weeks). The usage data may be repeated to simulate the usage data for the longer time period and/or used as input for a predictive algorithm to simulate the usage data for the longer time period, e.g., using machine-learning techniques.

The usage information may include, for example, a battery health metric (e.g., state of health, degradation rate, etc.), battery charging and/or discharging history, duration on alternating current (AC) mode (e.g., when the device 100 is plugged into a mains power source), duration in battery mode, system workload information, temperature associated with the battery 104 and/or system circuitry 102, usage scenario (e.g., if a lid of the device 100 is open or closed, if any peripheral devices are plugged into and/or powered by the device 100 such as a monitor, external memory drive, etc.). Examples of charging and/or discharging history include, but are not limited to, battery capacity at the beginning of a respective charging session, battery capacity at the end of the respective charging session, the length of the respective charging session, the amount of time between successive charging sessions, charging speed (e.g., whether fast or slow charging was employed), number of charge cycles, etc. The system workload information may include, for example, power consumption, associated workloads (e.g., streaming, web-surfing, word processing, general computing, etc.). It will be apparent that these are merely examples of usage information and other suitable usage information may be used in accordance with various embodiments herein.

In various embodiments, the control circuitry 128 may predict a future health metric of the battery 104 based on the usage information. For example, the future health metric may be the state of health, degradation rate, and/or another suitable metric that is indicative of the health of the battery 104. In some embodiments, the state of health may be represented as a percentage decline in the charge capacity of the battery at full charge. In some embodiments, the prediction may be made using a pre-trained deep learning and/or machine learning technique. For example, the prediction may use random forest regression and/or deep learning including long short-term memory (LSTM). The prediction may be made for any suitable interval or intervals in the future, such as 8 weeks to 2 years.

The control circuitry 128 may compare the future health metric to a threshold and take one or more actions based on the comparison. For example, if the comparison indicates that the future health of the battery 104 is predicted to be worse than the threshold level (e.g., the predicted state of health is less than a corresponding threshold or the predicted degradation rate is greater than the corresponding threshold), then the control circuitry 128 may trigger display of information, to the user (e.g., via UI 126), that is associated with one or more smart charging algorithms that are available for use on device 100. For example, the information may include a suggestion to switch to a different charging configuration to control charging of the battery 104. For example, the displayed information may include a suggestion to switch to a smart charging algorithm from an existing charging algorithm (e.g., a pre-defined (non-smart) charging algorithm or a different smart charging algorithm), or to change the parameters for an existing smart charging algorithm.

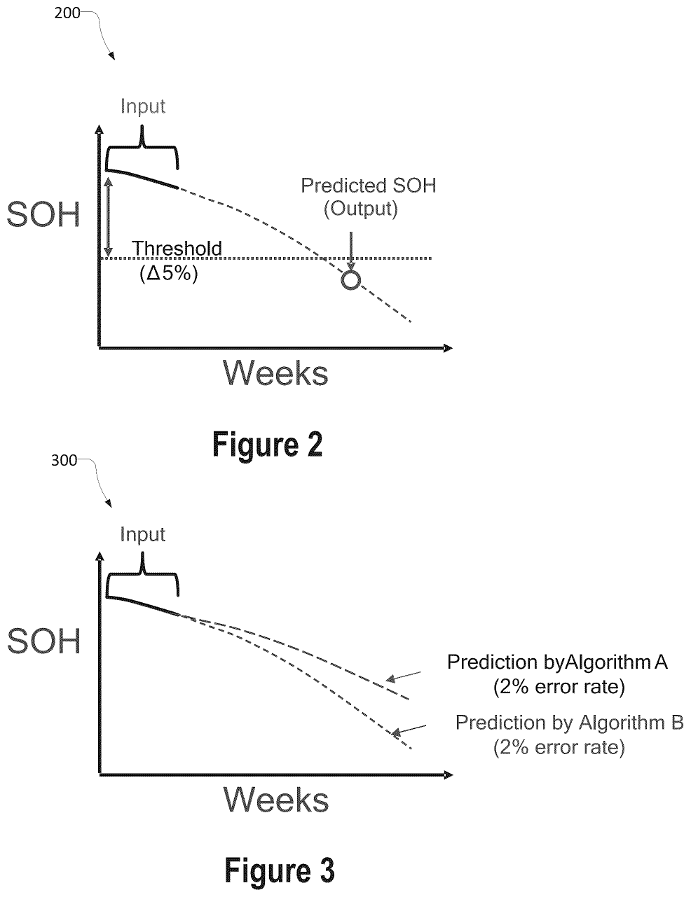

FIG. 2 illustrates an example graphical representation 200 of the predicted future state of health and comparison to a threshold, in accordance with various embodiments. In the example of FIG. 2, the usage information received as an input may correspond to sequential state of health data associated with the battery over a time period (0 to t1). The state of health of the battery at time period t2 may be predicted based on the usage information. In one example implementation, prediction of future state of health of a battery was predicted for 24 weeks in the future with 3.5% mean absolute error, based on 8 weeks of sequential state of health data from 1500 users/devices with 80% of the data used for training the machine learning model and 20% used for testing.

The predicted state of health may be compared to a threshold. The threshold may correspond to a percentage degradation of the state of health, such as 5% or another suitable value. As shown in FIG. 2, the predicted state of health is below the threshold, and thus the control circuitry may take or trigger one or more actions such as displaying information to the user, or generating an alert or notification, about one or more other charging configurations that are available as discussed herein.

Various embodiments herein may additionally or alternatively provide techniques to enable the user of a device (e.g., device 100) to compare multiple smart charging algorithms and/or configurations that are available for the device. For example, the control circuitry 128 may estimate future performance information for multiple charging configurations and trigger the display the performance information to the user (e.g., via UI 126), or trigger the generation of an alert or notification based on the performance information. In some embodiments, the display of the performance information for the multiple charging configurations may be triggered based on a comparison of a predicted health metric of the battery to a threshold as described above. Additionally, or alternatively, the display of the performance information for the multiple charging configurations may be triggered based on a request from the user (e.g., via the UI 126), based on a comparison of the performance information for the multiple charging configurations (e.g., if a different charging configuration than the one presently being used is predicted to perform better), and/or upon expiration of a timer (e.g., the performance information may be displayed to the user periodically).

The performance information may include, for example, the predicted health metric, an error rate, and/or an indication of charging time and associated effect on future battery health (e.g., the effect of using fast charging compared with slow charging). The error rate may correspond to a percentage of charge cycles in which the target charge state of the battery determined by the algorithm, such as 80% or 90%, is insufficient for the user's needs (e.g., the battery is fully discharged or discharged below a threshold). In some embodiments, the performance information may be obtained by providing the prior usage information to the multiple charging algorithms and receiving an output from each algorithm that indicates how the algorithm would perform under the same or similar usage. For example, the output may indicate how long the respective algorithm would keep the battery at different charge levels, such as 100%, 80%, and/or 60%.

In one example, algorithm A may sometimes regulate charging to 80% under the circumstances of the usage information and algorithm B may regulate charging sometimes to 80% and sometimes to 60%. The control circuitry 128 may predict the performance information, such as degradation in the state of health, based on a pre-defined association between the time period at different charge levels and corresponding degradation of the battery capacity. In one example, the state of health of the battery may degrade by 0.02% per hour in case of 100% charge, 0% per hour in case of <=60% charge, and a prorated value per hour for battery charge state between 60% and 100%. Accordingly, the control circuitry 128 may determine a total degradation in the state of health that is predicted to occur for the algorithms given the same usage information. The control circuitry 128 may further predict the associated error rate(s) based on the output received from the algorithms, or the error rate(s) may be indicated in the output received from the algorithms. Table 1 shows one example comparison of algorithm A and algorithm B in accordance with various embodiments, which also includes a comparison summary to indicate that algorithm B provides 1.25 times better longevity with a similar error rate.

TABLE 1

| | Pre-defined | | |
|---|---|---|---|
| | degradation | | |
| | rate | Algorithm A | Algorithm B |
| Duration of | 0.02% fade/ | 50 hours | 50 hours |
| 100% charge | hour | (=1% fade), | (=1% fade), |
| | | 0% error rate | 0% error rate |
| Duration of 80% | 0.01% fade/ | 150 hours | 100 hours |
| charge | hour | (=1.5% fade), | (=1% fade), |
| | | 2% error rate | 1% error rate |
| Duration of 60% | 0% fade/ | 0 hours | 50 hours |
| charge | hour | (=0% fade), | (=0% fade) |
| | | 0% error rate | 1% error rate |
| Estimated total | | −2.5% with | −2% with |
| capacity fade | | 2% error rate | 2% error rate |
| Comparison | | Baseline | 1.25x better |
| Summary | | | longevity with |
| | | | similar error rate |

In some embodiments, the performance information may be displayed to the user in table form, e.g., as shown in Table 1. Additionally, or alternatively, another suitable graphical representation may be used to display the performance information to the user.

For example, FIG. 3 is an example graphical representation 300 that may correspond to the data of FIG. 1. The graphical representation 300 of FIG. 3 depicts the predicted future degradation of the state of health if algorithm A and algorithm B are used. The prediction is made based on the same usage information (the input).

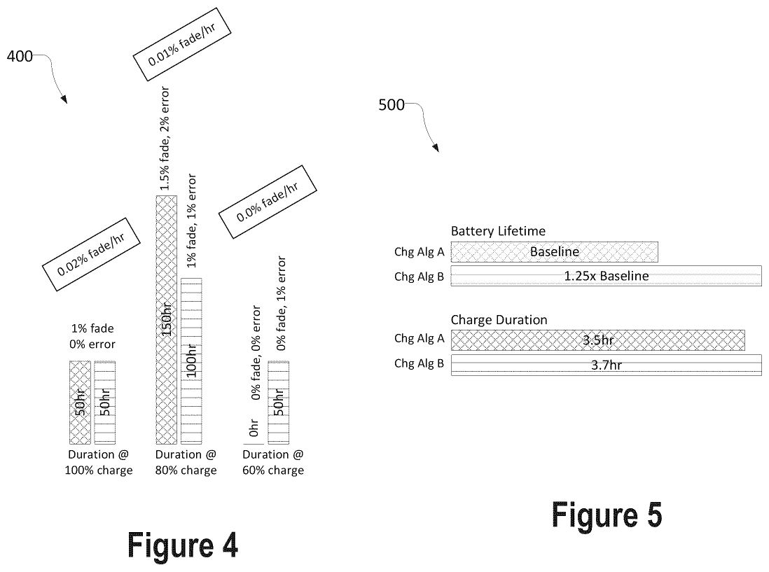

FIGS. 4 and 5 illustrate additional examples of how the performance information for multiple charging algorithms may be presented to the user. For example, FIG. 4 is a bar graph 400 of the data from Table 1, showing the duration that two different algorithms would hold the battery at 100% charge, 80% charge, and 60% charge, along with the associated degradation rate (e.g., fade/hour).

FIG. 5 depicts a bar graph 500 that shows a comparison of battery lifetime and charge duration for algorithm A (Chg Alg A) and algorithm B (Chg Alg B). As shown, algorithm B may take longer to charge the battery to a given charge state (e.g., 3.7 hours compared to 3.5 hours) but may provide a longer battery lifetime compared to algorithm A.

It will be apparent that FIGS. 3-5 and Table 1 are merely provided as examples, and numerous other techniques may be used to display and/or compare the performance information to the user in accordance with various embodiments herein. For example, one or more bar charts, line charts, radar charts, tables, and/or other suitable visual representations of the performance information may be use. Additionally, color coding may be used in some embodiments, e.g., to depict positive or negative attributes or comparisons between the charging algorithms.

Similar techniques may be used to generate and display performance information for different configurations of a same smart charging algorithm. Some smart charging algorithms may have one or more adjustable parameters. For example, the smart charging algorithm may have a first mode that increases battery lifetime at the expense of increased error rate, and a second mode that decreases the error rate at the expense of decreased battery lifetime. The techniques described herein may enable the user to compare the performance information for the different configurations and select the configuration that meets the user's goals.

In some embodiments, the user may specify a target longevity of the battery (e.g., 2-8 years or another suitable longevity). The control circuitry may receive the target longevity and determine the best charging algorithm and/or optimize the parameters of the charging algorithm based on the target longevity.

In some embodiments, the control circuitry may identify negative performance of the charging configuration that is being used, and take one or more actions based on the identification. For example, the control circuitry may identify if the error rate of the charging configuration is greater than a threshold and/or greater than the error rate of another charging configuration by a threshold. Based on the identification, the control circuitry may automatically disable the charging configuration (e.g., revert to a default charging algorithm) and/or present the performance information to the user to enable the user to switch the charging configuration.

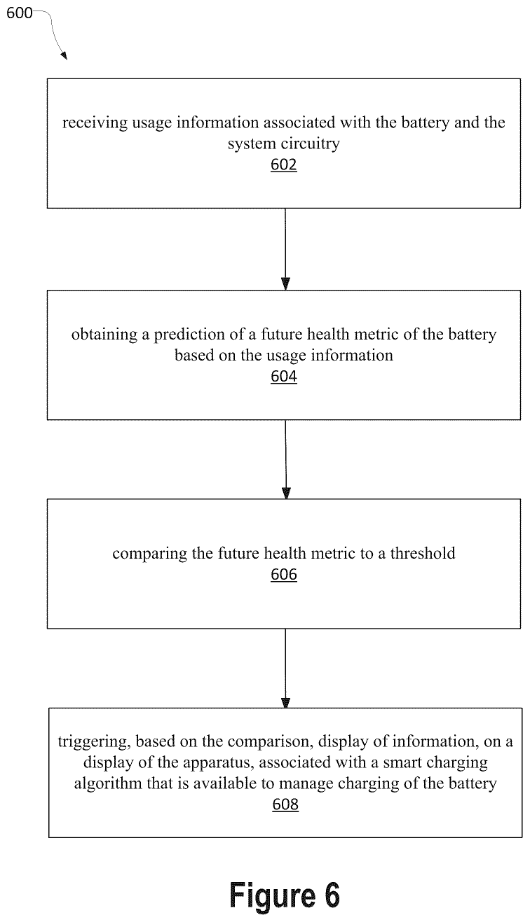

FIG. 6 illustrates an example process 600 in accordance with various embodiments. In some embodiments, the process 600 may be implemented by one or more components of a device, such as device 100. At 602, the process 600 may include receiving usage information associated with the battery and the system circuitry. In some embodiments, the usage information may include one or more of sequential battery health metric data, battery charging and discharging history, duration on AC mode, duration in battery mode, system workload information, temperature information, or usage scenario information.

At 604, the process may further include obtaining a prediction of a future health metric of the battery based on the usage information. For example, the future health metric may be a battery state of health or a battery degradation rate. In some embodiments, the device may generate the prediction of the future health metric. In other embodiments, the device may send the usage information to a remote system that generates the prediction. The device may then receive the prediction from the remote system.

At 606, the process 600 may include comparing the future health metric to a threshold. At 608, the process 600 may further include triggering, based on the comparison, display of information, on a display of the apparatus, associated with a smart charging algorithm that is available to manage charging of the battery. The information may be displayed using any suitable visual representation, including one or more tables and/or graphs, as described herein.

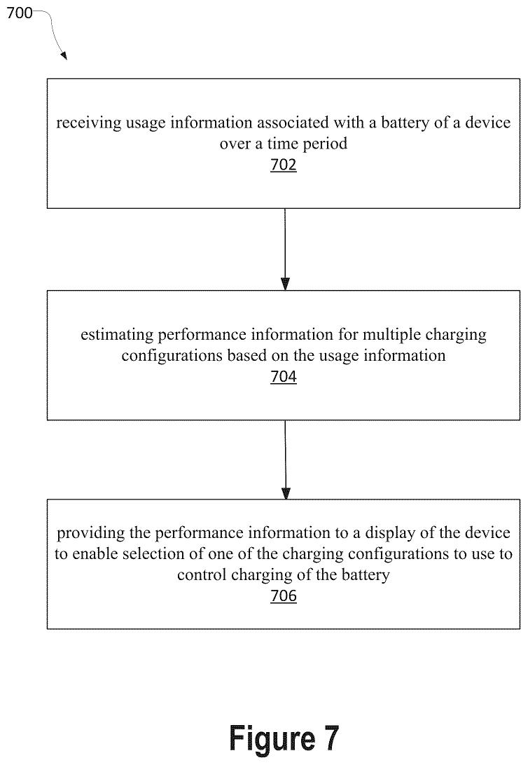

FIG. 7 illustrates another example process 700 in accordance with various embodiments. The process 700 may be performed by a device that includes a battery and/or a remote system in communication with the device. At 702, the process 700 may include receiving usage information associated with a battery of a device over a time period. The usage information may include, for example, one or more of sequential battery health metric data, battery charging and discharging history, duration on AC mode, duration in battery mode, system workload information, temperature information, or usage scenario information.

At 704, the process 700 may further include estimating performance information for multiple charging configurations based on the usage information. The charging configurations may include, for example, one or more predefined charging algorithms, one or more smart charging algorithms, and/or two or more configurations of a same smart charging algorithm. The performance information may include, for example, a health metric, an error rate, an indication of charging time and resulting effect on battery lifetime, etc.

At 706, the process 700 may further include providing the performance information to a display of the device to enable selection of one of the charging configurations to use to control charging of the battery. The performance information may be displayed using any suitable visual representation, including one or more tables and/or graphs, as described herein.

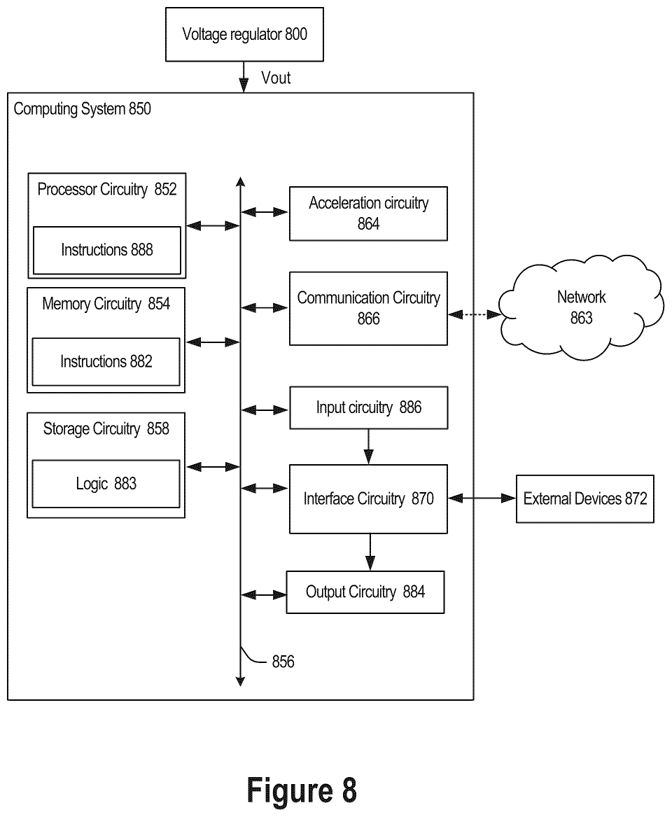

FIG. 8 illustrates an example of components that may be present in a computing system 850 for implementing the techniques (e.g., operations, processes, methods, and methodologies) described herein, in accordance with various embodiments. For example, the memory circuitry 854 may store instructions and the processor circuitry 852 may execute the instructions to perform the functions described herein.

The computing system 850 may include any combinations of the hardware or logical components referenced herein. The components may be implemented as ICs, portions thereof, discrete electronic devices, or other modules, instruction sets, programmable logic or algorithms, hardware, hardware accelerators, software, firmware, or a combination thereof adapted in the computing system 850, or as components otherwise incorporated within a chassis of a larger system. For one embodiment, at least one processor 852 may be packaged together with computational logic 882 and configured to practice aspects of various example embodiments described herein to form a System in Package (SiP) or a System on Chip (SoC).

The system 850 includes processor circuitry in the form of one or more processors 852. The processor circuitry 852 includes circuitry such as, but not limited to one or more processor cores and one or more of cache memory, low drop-out voltage regulators (LDOs), interrupt controllers, serial interfaces such as SPI, I2C or universal programmable serial interface circuit, real time clock (RTC), timer-counters including interval and watchdog timers, general purpose I/O, memory card controllers such as secure digital/multi-media card (SD/MMC) or similar, interfaces, mobile industry processor interface (MIPI) interfaces and Joint Test Access Group (JTAG) test access ports. In some implementations, the processor circuitry 852 may include one or more hardware accelerators (e.g., same or similar to acceleration circuitry 864), which may be microprocessors, programmable processing devices (e.g., FPGA, ASIC, etc.), or the like. The one or more accelerators may include, for example, computer vision and/or deep learning accelerators. In some implementations, the processor circuitry 852 may include on-chip memory circuitry, which may include any suitable volatile and/or non-volatile memory, such as DRAM, SRAM, EPROM, EEPROM, Flash memory, solid-state memory, and/or any other type of memory device technology, such as those discussed herein

The processor circuitry 852 may include, for example, one or more processor cores (CPUs), application processors, GPUs, RISC processors, Acorn RISC Machine (ARM) processors, CISC processors, one or more DSPs, one or more FPGAs, one or more PLDs, one or more ASICs, one or more baseband processors, one or more radio-frequency integrated circuits (RFIC), one or more microprocessors or controllers, a multi-core processor, a multithreaded processor, an ultra-low-voltage processor, an embedded processor, or any other known processing elements, or any suitable combination thereof. The processors (or cores) 852 may be coupled with or may include memory/storage and may be configured to execute instructions stored in the memory/storage to enable various applications or operating systems to run on the platform 850. The processors (or cores) 852 is configured to operate application software to provide a specific service to a user of the platform 850. In some embodiments, the processor(s) 852 may be a special-purpose processor(s)/controller(s) configured (or configurable) to operate according to the various embodiments herein.

As examples, the processor(s) 852 may include an Intel® Architecture Core™ based processor such as an i3, an i5, an i7, an i9 based processor; an Intel® microcontroller-based processor such as a Quark™, an Atom™, or other MCU-based processor; Pentium® processor(s), Xeon® processor(s), or another such processor available from Intel® Corporation, Santa Clara, California. However, any number other processors may be used, such as one or more of Advanced Micro Devices (AMD) Zen® Architecture such as Ryzen® or EPYC® processor(s), Accelerated Processing Units (APUs), MxGPUs, Epyc® processor(s), or the like; A5-A12 and/or S1-S4 processor(s) from Apple® Inc., Snapdragon™ or Centriq™ processor(s) from Qualcomm® Technologies, Inc., Texas Instruments, Inc.® Open Multimedia Applications Platform (OMAP)™ processor(s); a MIPS-based design from MIPS Technologies, Inc. such as MIPS Warrior M-class, Warrior I-class, and Warrior P-class processors; an ARM-based design licensed from ARM Holdings, Ltd., such as the ARM Cortex-A, Cortex-R, and Cortex-M family of processors; the ThunderX2® provided by Cavium™, Inc.; or the like. In some implementations, the processor(s) 852 may be a part of a system on a chip (SoC), System-in-Package (SiP), a multi-chip package (MCP), and/or the like, in which the processor(s) 852 and other components are formed into a single integrated circuit, or a single package, such as the Edison™ or Galileo™ SoC boards from Intel® Corporation. Other examples of the processor(s) 852 are mentioned elsewhere in the present disclosure.

The system 850 may include or be coupled to acceleration circuitry 864, which may be embodied by one or more AI/ML accelerators, a neural compute stick, neuromorphic hardware, an FPGA, an arrangement of GPUs, one or more SoCs (including programmable SoCs), one or more CPUs, one or more digital signal processors, dedicated ASICs (including programmable ASICs), PLDs such as complex (CPLDs) or high complexity PLDs (HCPLDs), and/or other forms of specialized processors or circuitry designed to accomplish one or more specialized tasks. These tasks may include AI/ML processing (e.g., including training, inferencing, and classification operations), visual data processing, network data processing, object detection, rule analysis, or the like. In FPGA-based implementations, the acceleration circuitry 864 may comprise logic blocks or logic fabric and other interconnected resources that may be programmed (configured) to perform various functions, such as the procedures, methods, functions, etc. of the various embodiments discussed herein. In such implementations, the acceleration circuitry 864 may also include memory cells (e.g., EPROM, EEPROM, flash memory, static memory (e.g., SRAM, anti-fuses, etc.) used to store logic blocks, logic fabric, data, etc. in LUTs and the like.

In some implementations, the processor circuitry 852 and/or acceleration circuitry 864 may include hardware elements specifically tailored for machine learning and/or artificial intelligence (AI) functionality. In these implementations, the processor circuitry 852 and/or acceleration circuitry 864 may be, or may include, an AI engine chip that can run many different kinds of AI instruction sets once loaded with the appropriate weightings and training code. Additionally or alternatively, the processor circuitry 852 and/or acceleration circuitry 864 may be, or may include, AI accelerator(s), which may be one or more of the aforementioned hardware accelerators designed for hardware acceleration of AI applications. As examples, these processor(s) or accelerators may be a cluster of artificial intelligence (AI) GPUs, tensor processing units (TPUs) developed by Google® Inc., Real AI Processors (RAPS™) provided by AlphaICs®, Nervana™ Neural Network Processors (NNPs) provided by Intel® Corp., Intel® Movidius™ Myriad™ X Vision Processing Unit (VPU), NVIDIA® PX™ based GPUs, the NM500 chip provided by General Vision®, Hardware 3 provided by Tesla®, Inc., an Epiphany™ based processor provided by Adapteva®, or the like. In some embodiments, the processor circuitry 852 and/or acceleration circuitry 864 and/or hardware accelerator circuitry may be implemented as AI accelerating co-processor(s), such as the Hexagon 685 DSP provided by Qualcomm®, the PowerVR 2NX Neural Net Accelerator (NNA) provided by Imagination Technologies Limited®, the Neural Engine core within the Apple® Bionic SoC, the Neural Processing Unit (NPU) within the HiSilicon Kirin 970 provided by Huawei®, and/or the like. In some hardware-based implementations, individual subsystems of system 850 may be operated by the respective AI accelerating co-processor(s), AI GPUs, TPUs, or hardware accelerators (e.g., FPGAs, ASICS, DSPs, SoCs, etc.), etc., that are configured with appropriate logic blocks, bit stream(s), etc. to perform their respective functions.

The system 850 also includes system memory 854. Any number of memory devices may be used to provide for a given amount of system memory. As examples, the memory 854 may be, or include, volatile memory such as random access memory (RAM), static RAM (SRAM), dynamic RAM (DRAM), synchronous DRAM (SDRAM), RAMBUS® Dynamic Random Access Memory (RDRAM®), and/or any other desired type of volatile memory device. Additionally or alternatively, the memory 854 may be, or include, non-volatile memory such as read-only memory (ROM), erasable programmable ROM (EPROM), electrically erasable programmable (EEPROM), flash memory, non-volatile RAM, ferroelectric RAM, phase-change memory (PCM), flash memory, and/or any other desired type of non-volatile memory device. Access to the memory 854 is controlled by a memory controller. The individual memory devices may be of any number of different package types such as single die package (SDP), dual die package (DDP) or quad die package (Q17P). Any number of other memory implementations may be used, such as dual inline memory modules (DIMMs) of different varieties including but not limited to microDIMMs or MiniDIMMs.

Storage circuitry 858 provides persistent storage of information such as data, applications, operating systems and so forth. In an example, the storage 858 may be implemented via a solid-state disk drive (SSDD) and/or high-speed electrically erasable memory (commonly referred to as “flash memory”). Other devices that may be used for the storage 858 include flash memory cards, such as SD cards, microSD cards, XD picture cards, and the like, and USB flash drives. In an example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, phase change RAM (PRAM), resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a Domain Wall (DW) and Spin Orbit Transfer (SOT) based device, a thyristor based memory device, a hard disk drive (HDD), micro HDD, of a combination thereof, and/or any other memory. The memory circuitry 854 and/or storage circuitry 858 may also incorporate three-dimensional (3D) cross-point (XPOINT) memories from Intel® and Micron®.

The memory circuitry 854 and/or storage circuitry 858 is/are configured to store computational logic 883 in the form of software, firmware, microcode, or hardware-level instructions to implement the techniques described herein. The computational logic 883 may be employed to store working copies and/or permanent copies of programming instructions, or data to create the programming instructions, for the operation of various components of system 850 (e.g., drivers, libraries, application programming interfaces (APIs), etc.), an operating system of system 850, one or more applications, and/or for carrying out the embodiments discussed herein. The computational logic 883 may be stored or loaded into memory circuitry 854 as instructions 882, or data to create the instructions 882, which are then accessed for execution by the processor circuitry 852 to carry out the functions described herein. The processor circuitry 852 and/or the acceleration circuitry 864 accesses the memory circuitry 854 and/or the storage circuitry 858 over the interconnect (IX) 856. The instructions 882 direct the processor circuitry 852 to perform a specific sequence or flow of actions, for example, as described with respect to flowchart(s) and block diagram(s) of operations and functionality depicted previously. The various elements may be implemented by assembler instructions supported by processor circuitry 852 or high-level languages that may be compiled into instructions 888, or data to create the instructions 888, to be executed by the processor circuitry 852. The permanent copy of the programming instructions may be placed into persistent storage devices of storage circuitry 858 in the factory or in the field through, for example, a distribution medium (not shown), through a communication interface (e.g., from a distribution server (not shown)), over-the-air (OTA), or any combination thereof.

The IX 856 couples the processor 852 to communication circuitry 866 for communications with other devices, such as a remote server (not shown) and the like. The communication circuitry 866 is a hardware element, or collection of hardware elements, used to communicate over one or more networks 863 and/or with other devices. In one example, communication circuitry 866 is, or includes, transceiver circuitry configured to enable wireless communications using any number of frequencies and protocols such as, for example, the Institute of Electrical and Electronics Engineers (IEEE) 802.11 (and/or variants thereof), IEEE 802.23.4, Bluetooth® and/or Bluetooth® low energy (BLE), ZigBee®, LoRaWAN™ (Long Range Wide Area Network), a cellular protocol such as 3GPP LTE and/or Fifth Generation (5G)/New Radio (NR), and/or the like. Additionally or alternatively, communication circuitry 866 is, or includes, one or more network interface controllers (NICs) to enable wired communication using, for example, an Ethernet connection, Controller Area Network (CAN), Local Interconnect Network (LIN), DeviceNet, ControlNet, Data Highway+, or PROFINET, among many others.

The IX 856 also couples the processor 852 to interface circuitry 870 that is used to connect system 850 with one or more external devices 872. The external devices 872 may include, for example, sensors, actuators, positioning circuitry (e.g., global navigation satellite system (GNSS)/Global Positioning System (GPS) circuitry), client devices, servers, network appliances (e.g., switches, hubs, routers, etc.), integrated photonics devices (e.g., optical neural network (ONN) integrated circuit (IC) and/or the like), and/or other like devices.

In some optional examples, various input/output (I/O) devices may be present within or connected to, the system 850, which are referred to as input circuitry 886 and output circuitry 884. The input circuitry 886 and output circuitry 884 include one or more user interfaces designed to enable user interaction with the platform 850 and/or peripheral component interfaces designed to enable peripheral component interaction with the platform 850. Input circuitry 886 may include any physical or virtual means for accepting an input including, inter alia, one or more physical or virtual buttons (e.g., a reset button), a physical keyboard, keypad, mouse, touchpad, touchscreen, microphones, scanner, headset, and/or the like. The output circuitry 884 may be included to show information or otherwise convey information, such as sensor readings, actuator position(s), or other like information. Data and/or graphics may be displayed on one or more user interface components of the output circuitry 884. Output circuitry 884 may include any number and/or combinations of audio or visual display, including, inter alia, one or more simple visual outputs/indicators (e.g., binary status indicators (e.g., light emitting diodes (LEDs)) and multi-character visual outputs, or more complex outputs such as display devices or touchscreens (e.g., Liquid Crystal Displays (LCD), LED displays, quantum dot displays, projectors, etc.), with the output of characters, graphics, multimedia objects, and the like being generated or produced from the operation of the platform 850. The output circuitry 884 may also include speakers and/or other audio emitting devices, printer(s), and/or the like. Additionally or alternatively, sensor(s) may be used as the input circuitry 884 (e.g., an image capture device, motion capture device, or the like) and one or more actuators may be used as the output device circuitry 884 (e.g., an actuator to provide haptic feedback or the like). Peripheral component interfaces may include, but are not limited to, a non-volatile memory port, a USB port, an audio jack, a power supply interface, etc. In some embodiments, a display or console hardware, in the context of the present system, may be used to provide output and receive input of an edge computing system; to manage components or services of an edge computing system; identify a state of an edge computing component or service; or to conduct any other number of management or administration functions or service use cases.

The components of the system 850 may communicate over the IX 856. The IX 856 may include any number of technologies, including ISA, extended ISA, I2C, SPI, point-to-point interfaces, power management bus (PMBus), PCI, PCIe, PCIx, Intel® UPI, Intel® Accelerator Link, Intel® CXL, CAPI, OpenCAPI, Intel® QPI, UPI, Intel® OPA IX, RapidIO™ system IXs, CCIX, Gen-Z Consortium IXs, a HyperTransport interconnect, NVLink provided by NVIDIA®, a Time-Trigger Protocol (TTP) system, a FlexRay system, PROFIBUS, and/or any number of other IX technologies. The IX 856 may be a proprietary bus, for example, used in a SoC based system.

The number, capability, and/or capacity of the elements of system 850 may vary, depending on whether computing system 850 is used as a stationary computing device (e.g., a server computer in a data center, a workstation, a desktop computer, etc.) or a mobile computing device (e.g., a smartphone, tablet computing device, laptop computer, game console, IoT device, etc.). In various implementations, the computing device system 850 may comprise one or more components of a data center, a desktop computer, a workstation, a laptop, a smartphone, a tablet, a digital camera, a smart appliance, a smart home hub, a network appliance, and/or any other device/system that processes data.

The techniques described herein can be performed partially or wholly by software or other instructions provided in a machine-readable storage medium (e.g., memory). The software is stored as processor-executable instructions (e.g., instructions to implement any other processes discussed herein). Instructions associated with the flowchart (and/or various embodiments) and executed to implement embodiments of the disclosed subject matter may be implemented as part of an operating system or a specific application, component, program, object, module, routine, or other sequence of instructions or organization of sequences of instructions.

The storage medium can be a tangible, non-transitory machine readable medium such as read only memory (ROM), random access memory (RAM), flash memory devices, floppy and other removable disks, magnetic storage media, optical storage media (e.g., Compact Disk Read-Only Memory (CD ROMS), Digital Versatile Disks (DVDs)), among others.

The storage medium may be included, e.g., in a communication device, a computing device, a network device, a personal digital assistant, a manufacturing tool, a mobile communication device, a cellular phone, a notebook computer, a tablet, a game console, a set top box, an embedded system, a TV (television), or a personal desktop computer.

### Examples

Some non-limiting examples of various embodiments are provided below.

Example 1 is an apparatus comprising: a power interface to be coupled to a battery; system circuitry to be powered by the battery; and control circuitry. The control circuitry is to: receive usage information associated with the battery and the system circuitry; obtain a prediction of a future health metric of the battery based on the usage information; compare the future health metric to a threshold; and trigger, based on the comparison, display of information, on a display of the apparatus, associated with a smart charging algorithm that is available to manage charging of the battery.

Example 2 is the apparatus of example 1, wherein the future health metric is a battery state of health or a battery degradation rate.

Example 3 is the apparatus of example 1 or example 2, wherein the usage information includes one or more of sequential battery health metric data, battery charging and discharging history, duration on alternating current (AC) mode, duration in battery mode, system workload information, temperature information, or usage scenario information.

Example 4 is the apparatus of any of examples 1-3, wherein the displayed information includes performance information for multiple smart charging configurations that are available to manage charging of the battery.

Example 5 is the apparatus of example 4, wherein the performance information includes an indication of battery capacity degradation.

Example 6 is the apparatus of example 4 or example 5, wherein the performance information includes an error rate associated with the respective smart charging configurations.

Example 7 is the apparatus of any one of examples 4-6, wherein the multiple smart charging configurations include different smart charging algorithms.

Example 8 is the apparatus of any one of examples 4-7, wherein the multiple smart charging configurations include different parameter configurations of the same smart charging algorithm.

Example 9 is the apparatus of any one of examples 1-8, wherein, to obtain the prediction, the control circuitry is to: generate the prediction; or send the usage information to a remote system and receive the prediction from the remote system.

Example 10 is one or more non-transitory computer-readable media (NTCRM) having instructions, stored thereon, that when executed by one or more processors of a system configure the system to: receive usage information associated with a battery of a device over a time period; estimate performance information for multiple charging configurations based on the usage information; and provide the performance information to a display of the device to enable selection of one of the charging configurations to use to control charging of the battery.

Example 11 is the one or more NTCRM of example 10, wherein the multiple charging configurations include different smart charging algorithms.

Example 12 is the one or more NTCRM of example 10 or example 11, wherein the multiple charging configurations include different parameter configurations of a same smart charging algorithm.

Example 13 is the one or more NTCRM of any of examples 10-12, wherein the performance information includes a health metric and an error rate.

Example 14 is the one or more NTCRM of any of examples 10-13, wherein the usage information includes one or more of sequential battery health metric data, battery charging and discharging history, duration on alternating current (AC) mode, duration in battery mode, system workload information, temperature information, or usage scenario information.

Example 15 is the one or more NTCRM of any of examples 10-14, wherein the system is included in the device or in a remote system.

Example 16 is the one or more NTCRM of any of examples 10-15, wherein the provide the performance information to the display is triggered based on one or more of: a comparison of the estimated performance information for a current charging configuration to one or more thresholds; a request by a user of the device; or expiration of a timer.

Example 17 includes a system comprising: a battery; system circuitry to be powered by the battery; a user interface; and control circuitry. The control circuitry is to: obtain usage information associated with the battery and the system circuitry over a time period; estimate, based on the usage information, performance information of the battery associated with a smart charging algorithm, wherein the estimated performance information includes a future health metric; compare the future health metric to a threshold; and display the performance information on the user interface based on the comparison.

Example 18 is the system of example 17, wherein the performance information is estimated and displayed for multiple smart charging algorithms.

Example 19 is the system of example 17 or example 18, wherein the performance information further includes an error rate.

Example 20 is the system of any of examples 17-19, wherein the usage information includes one or more of sequential battery health metric data, battery charging and discharging history, duration on alternating current (AC) mode, duration in battery mode, system workload information, temperature information, or usage scenario information.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

The terms “substantially,” “close,” “approximately,” “near,” and “about,” generally refer to being within +/−10% of a target value. Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, the phrases “A and/or B” and “A or B” mean (A), (B), or (A and B). For the purposes of the present disclosure, the phrase “A, B, and/or C” means (A), (B), (C), (A and B), (A and C), (B and C), or (A, B, and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “circuitry” may refer to, be part of, or include an Application Specific Integrated Circuit (ASIC), an electronic circuit, a processor (shared, dedicated, or group), a combinational logic circuit, and/or other suitable hardware components that provide the described functionality. As used herein, “computer-implemented method” may refer to any method executed by one or more processors, a computer system having one or more processors, a mobile device such as a smartphone (which may include one or more processors), a tablet, a laptop computer, a set-top box, a gaming console, and so forth.

The terms “coupled,” “communicatively coupled,” along with derivatives thereof are used herein. The term “coupled” may mean two or more elements are in direct physical or electrical contact with one another, may mean that two or more elements indirectly contact each other but still cooperate or interact with each other, and/or may mean that one or more other elements are coupled or connected between the elements that are said to be coupled with each other. The term “directly coupled” may mean that two or more elements are in direct contact with one another. The term “communicatively coupled” may mean that two or more elements may be in contact with one another by a means of communication including through a wire or other interconnect connection, through a wireless communication channel or link, and/or the like.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional elements.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well-known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

What is claimed is:

1. An apparatus comprising:
a power interface to be coupled to a battery;
system circuitry to be powered by the battery; and
control circuitry to:
receive usage information associated with the battery and the system circuitry;
obtain a prediction of a future health metric of the battery based on the usage information;
compare the future health metric to a threshold; and
trigger, based on the comparison, display of information, on a display of the apparatus, associated with a smart charging algorithm that is available to manage charging of the battery.

2. The apparatus of claim 1, wherein the future health metric is a battery state of health or a battery degradation rate.

3. The apparatus of claim 1, wherein the usage information includes one or more of sequential battery health metric data, battery charging and discharging history, duration on alternating current (AC) mode, duration in battery mode, system workload information, temperature information, or usage scenario information.

4. The apparatus of claim 1, wherein the displayed information includes performance information for multiple smart charging configurations that are available to manage charging of the battery.

5. The apparatus of claim 4, wherein the performance information includes an indication of battery capacity degradation.

6. The apparatus of claim 4, wherein the performance information includes an error rate associated with the respective smart charging configurations.

7. The apparatus of claim 4, wherein the multiple smart charging configurations include different smart charging algorithms.

8. The apparatus of claim 4, wherein the multiple smart charging configurations include different parameter configurations of the same smart charging algorithm.

9. The apparatus of claim 1, wherein, to obtain the prediction, the control circuitry is to:
generate the prediction; or
send the usage information to a remote system and receive the prediction from the remote system.

10. One or more non-transitory computer-readable media (NTCRM) having instructions, stored thereon, that when executed by one or more processors of a system configure the system to:
receive usage information associated with a battery of a device over a time period;
estimate performance information for multiple charging configurations based on the usage information; and
provide the performance information to a display of the device to enable selection of one of the charging configurations to use to control charging of the battery.

11. The one or more NTCRM of claim 10, wherein the multiple charging configurations include different smart charging algorithms.

12. The one or more NTCRM of claim 10, wherein the multiple charging configurations include different parameter configurations of a same smart charging algorithm.

13. The one or more NTCRM of claim 10, wherein the performance information includes a health metric and an error rate.

14. The one or more NTCRM of claim 10, wherein the usage information includes one or more of sequential battery health metric data, battery charging and discharging history, duration on alternating current (AC) mode, duration in battery mode, system workload information, temperature information, or usage scenario information.

15. The one or more NTCRM of claim 10, wherein the system is included in the device or in a remote system.

16. The one or more NTCRM of claim 10, wherein the provide the performance information to the display is triggered based on one or more of:
a comparison of the estimated performance information for a current charging configuration to one or more thresholds;
a request by a user of the device; or
expiration of a timer.

17. A system comprising:
a battery;
system circuitry to be powered by the battery;
a user interface; and
control circuitry to:
obtain usage information associated with the battery and the system circuitry over a time period;
estimate, based on the usage information, performance information of the battery associated with a smart charging algorithm, wherein the estimated performance information includes a future health metric;
compare the future health metric to a threshold; and
display the performance information on the user interface based on the comparison.

18. The system of claim 17, wherein the performance information is estimated and displayed for multiple smart charging algorithms.

19. The system of claim 17, wherein the performance information further includes an error rate.

20. The system of claim 17, wherein the usage information includes one or more of sequential battery health metric data, battery charging and discharging history, duration on alternating current (AC) mode, duration in battery mode, system workload information, temperature information, or usage scenario information.
